(19) United States
(12) Patent Application Publication
(10) Pub. No.: US 2016/0079266 A1
(43) Pub. Date: Mar. 17, 2016

(54) SEMICONDUCTOR MEMORY DEVICE AND METHOD FOR MANUFACTURING THE SAME

(71) Applicant: Kabushiki Kaisha Toshiba, Minato-ku (JP)

(72) Inventors: Nozomi KIDO, Yokkaichi (JP); Masao IWASE, Yokkaichi (JP); Tadashi IGUCHI, Yokkaichi (JP)

(73) Assignee: Kabushiki Kaisha Toshiba, Minato-ku (JP)

(21) Appl. No.: 14/657,417

(22) Filed: Mar. 13, 2015

Related U.S. Application Data
(60) Provisional application No. 62/049,182, filed on Sep. 11, 2014.

(51) Int. Cl. H01L 27/115; H01L 23/528

(52) U.S. Cl. CPC H01L 27/11582; H01L 27/1157; H01L 23/528

(57) ABSTRACT

According to one embodiment, a semiconductor memory device includes a stacked body, a selection gate electrode, a semiconductor pillar, a first insulating member, a second insulating member, a third insulating member. The stacked body is provided on the substrate. The selection gate electrode is provided on the stacked body. The first insulating member divides the stacked body in a first direction. The second insulating member is provided in an area directly above the first insulating member and dividing the selection gate electrode in the first direction. The third insulating member is provided in a region other than the area directly above the first insulating member and dividing the selection gate electrode in the first direction. An average width of the second insulating member in the first direction is larger than an average width of the third insulating member in the first direction.

### CROSS-REFERENCE TO RELATED APPLICATIONS

This application is based upon and claims the benefit of priority from U.S. Provisional Patent Application 62/049,182, filed on Sep. 11, 2014; the entire contents of which are incorporated herein by reference.

### FIELD

Embodiments described herein relate generally to a semiconductor memory device and a method for manufacturing the same.

### BACKGROUND

In order to reduce the bit unit price of a semiconductor device and increase its capacity, it is effective to achieve high integration of memory cells. As a technology for achieving the high integration of memory cells, there is a method for three-dimensionally integrating memory cells by stacking them. In such a three-dimensionally integrated semiconductor device, a plurality of electrodes are stacked. These electrodes are divided by slits, and silicidation of the divided electrodes is performed via these slits.

### BRIEF DESCRIPTION OF THE DRAWINGS

FIG. 1 is a perspective view illustrating a semiconductor memory device according to a first embodiment;

FIG. 2 is a cross-sectional view illustrating the semiconductor memory device according to the first embodiment;

FIGS. 3A to 7C are process cross-sectional views illustrating the method of manufacturing the semiconductor memory device according to the first embodiment, and show cross sections corresponding to those taken along line A-A′ of FIG. 1; and

FIGS. 8A to 10 are process cross-sectional views illustrating the method of manufacturing the semiconductor memory device according to a second embodiment, and show cross sections corresponding to those taken along line A-A′ of FIG. 1.

### DETAILED DESCRIPTION

In general, according to one embodiment, a semiconductor memory device includes a substrate, a stacked body, a selection gate electrode, a semiconductor pillar, a first insulating member, a second insulating member, a third insulating member. The stacked body is provided on the substrate. The stacked body includes a plurality of control gate electrodes and a plurality of insulating films. Each of the plurality of control gate electrodes and each of the plurality of insulating films are alternately stacked in a stacking direction. The selection gate electrode is stacked on the stacked body. The first semiconductor pillar extends in the stacking direction and provided in the selection gate electrode and the stacked body. The first insulating member divides the stacked body in a first direction. The second insulating member is provided in an area directly above the first insulating member and dividing the selection gate electrode in the first direction. The third insulating member is provided in a region other than the area directly above the first insulating member and dividing the selection gate electrode in the first direction. An average width of the second insulating member in the first direction is larger than an average width of the third insulating member in the first direction.

Hereinafter, embodiments of the invention will be described.

### First Embodiment

A first embodiment will first be described.

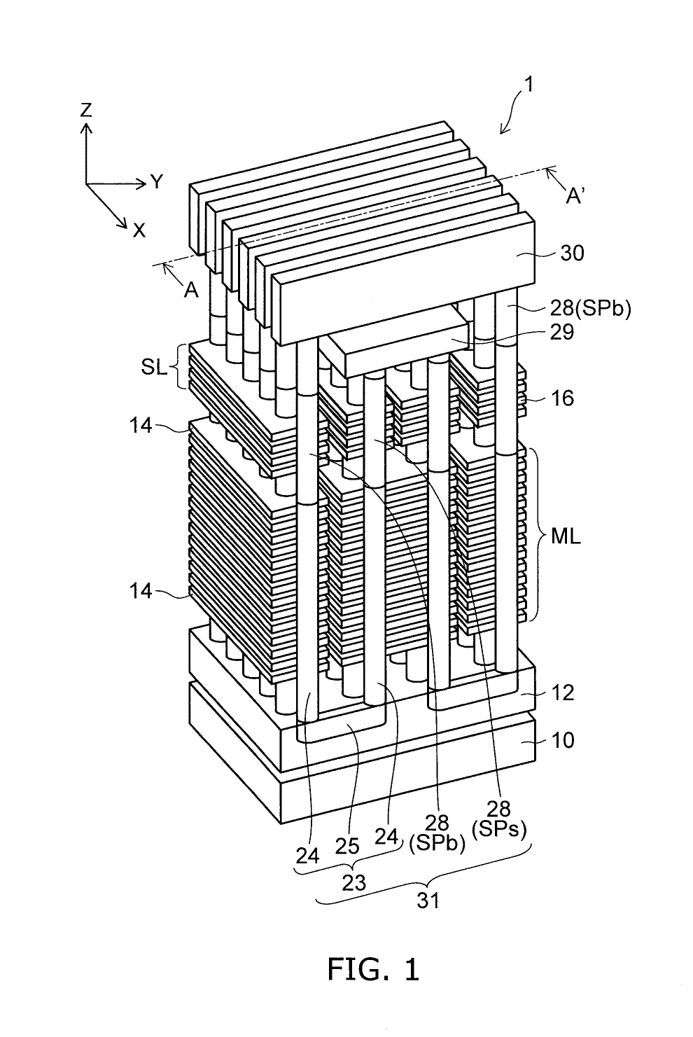

FIG. 1 is a perspective view illustrating a semiconductor memory device according to the embodiment.

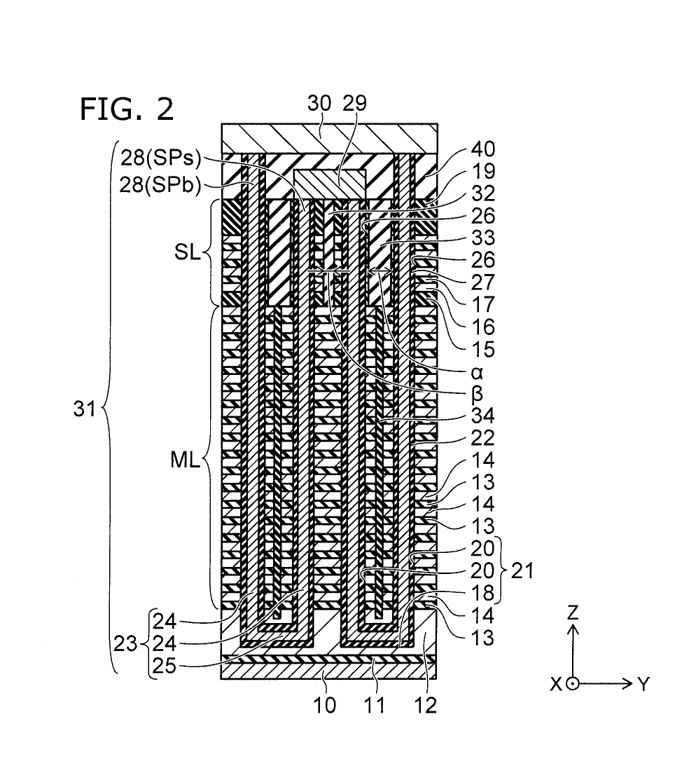

FIG. 2 is a cross-sectional view illustrating the semiconductor memory device according to the embodiment.

In FIG. 1, in order to make the drawing more visible, only a silicon substrate and a conductive part are shown, and the illustration of an insulating part is omitted.

As shown in FIGS. 1 and 2, the silicon substrate 10 is provided in the semiconductor memory device 1 according to the embodiment.

In the specification, for convenience of explanation, an XYZ orthogonal coordinate system is introduced. In this coordinate system, it is assumed that two directions which are parallel to the major surface of the silicon substrate 10 and are orthogonal to each other are an X-direction (second direction) and a Y-direction (first direction), and that a direction which is orthogonal to both the X-direction and the Y-direction, that is, the stacking direction of respective layers is a Z-direction (third direction).

An insulating film 11 is provided on the silicon substrate 10, and a back gate conductive film 12 is provided thereon.

A plurality of insulating films 13 and electrode films 14 are alternately provided on the back gate conductive film 12 to form a stacked body ML. The electrode film 14 is formed of a material such as polysilicon.

There is provided, within the stacked body ML, an insulating member 34 in plural numbers which is a first insulating member extending on an XZ plane and is plate-shaped. Thereby, the stacked body ML is divided in the Y-direction, and the divided electrode films 14 serve as a plurality of control gate electrodes extending in the X-direction. An insulating film 15 is provided on the stacked body ML. A plurality of electrode films 16 and insulating films 17 are provided in this order on the insulating film 15, and for example, a total of 7 layers are provided, and an insulating layer 19 is provided thereon. The electrode film 16 is constituted of, for example, polysilicon or the like. A stacked body SL is constituted by the insulating films 15, 17 and 19 and the electrode film 16. The stacked body SL is divided along the Y-direction, and the divided electrode films 16 serve as a plurality of selection gate electrodes extending in the X-direction.

Insulating members 32 and 33 are provided between the stacked bodies SL adjacent to each other in the Y-direction. The insulating member 33 that is a second insulating member is provided in an area directly above the insulating member 34, and the width α of the insulating member 33 in the Y-direction is larger than that of the insulating member 34 in the Y-direction. The insulating member 32 that is a third insulating member is provided between the two insulating members 33 adjacent to each other, and the width β of the insulating member 32 in the Y-direction is smaller than the width α of the insulating member 33 in the Y-direction.

Namely, although the electrode film 16 extends in the same direction (X-direction) as the electrode film 14, its alignment period is half, and the insulating member 33 whose width is large and the insulating member 32 whose width is small along the Y-direction are alternately provided between the electrode films 16 adjacent to each other.

In addition, a plurality of through-holes 20 extending in the Z-direction are formed so as to penetrate the stacked body ML. Each through-hole 20 penetrates the electrode film 14 in each stage, and its lower end reaches the back gate conductive film 12.

Furthermore, the through-holes 20 are aligned, for example, along the X-direction and the Y-direction in the form of a matrix. Then, the electrode film 14 extends in the X-direction, and the through-holes 20 in two rows aligned in the X-direction penetrate the same electrode film 14.

Moreover, a communication hole 18 is formed within an upper portion of the back gate conductive film 12 such that a lower end portion of one through-hole 20 is communicated with a lower end portion of the adjacent through-hole 20 spaced in the Y-direction as seen from the one through-hole 20. Thereby, a pair of the through-holes 20 adjacent to each other in the Y-direction and the communication hole 18 communicating them with each other form one continuous U-shaped hole 21. In addition, each of the two through-holes 20 that are communicated with each other by the communication hole 18 penetrates a different electrode film 14. A plurality of U-shaped holes 21 are formed within the stacked body ML.

A memory film 22 is provided on the inner face of the U-shaped hole 21. The memory film 22 is formed by stacking a block insulating film, a charge storage film and a tunnel insulating film. The memory film 22 is in contact with the back gate conductive film 12, the insulating film 13 and the electrode film 14.

An impurity-doped semiconductor material, for example, polysilicon is embedded within the U-shaped hole 21. Thereby, a U-shaped silicon member 23 is provided within the U-shaped hole 21. In the U-shaped silicon member 23, a part located within the through-hole 20 is a semiconductor pillar 24, and a part located within the communication hole 21 is a connection member 25.

The shape of the semiconductor pillar 24 is a columnar shape extending in the Z-direction, and is, for example, a cylindrical shape. In addition, the shape of the connection member 25 is a columnar shape extending in the Y-direction, and is, for example, a quadrangular prism shape. The two semiconductor pillars 24 and one connection member 25 constituting the U-shaped silicon member 23 is formed seamlessly along the longitudinal direction of the U-shaped silicon member 23. The U-shaped silicon member 23 is insulated from the back gate conductive film 12 and the electrode film 14, by the memory film 22.

In the stacked body SL, a plurality of through-holes 26 are formed. Each of the through-holes 26 is formed in an area directly above each of the through-holes 20, and communicates with each of the through-holes 21. Here, since the electrode film 16 extends in the X-direction, the through-holes 20 aligned in the X-direction penetrate the same selection gate electrode. The alignment period of the through-holes 26 in the Y-direction is the same as that of the selection gate electrode, and the phase of the alignment is also the same as that of the selection gate electrode. Therefore, the plurality of through-holes 26 aligned in the Y-direction correspond to the electrode films 16 on a one-to-one basis, and each of them penetrates a different electrode film 16.

A gate insulating film 27 is formed on the inner face of the through-hole 26. In addition, for example, polysilicon is embedded within the through-hole 26 to thereby serve as a semiconductor pillar 28. The shape of the semiconductor pillar 28 is a columnar shape extending in the Z-direction, and is, for example, a cylindrical shape. Furthermore, the lower end portion of the semiconductor pillar 28 is connected to the upper end portion of the semiconductor pillar 24 formed in an area directly thereabove. Thereby, the semiconductor pillars 28 and 24 penetrate the stacked bodies ML and SL, and the stacked body ML is divided for each semiconductor pillar 24 in two rows, and the stacked body SL is divided for each semiconductor pillar 28 in one row. Furthermore, the semiconductor pillar 28 is also insulated by the gate insulating film 27 from the electrode film 16.

A source line electrode 29 is provided on an interlayer insulating film 19, and is connected to one semiconductor pillar of the U-shaped silicon member 23 through the semiconductor pillar 28 (SPs). An insulating film 40 is provided on the insulating film 19 so as to cover the source line 29, and a plurality of bit lines 30 extending in the Y-direction are provided on the insulating film 40. The bit line 30 is connected, via the semiconductor pillar 28 (SPb), to the semiconductor pillar 24 which is not connected to the source line 29 of the U-shaped silicon member 23. The semiconductor pillar 28 penetrates the insulating layer 40, and is connected to the bit line 30.

A U-shaped pillar 31 is constituted by the U-shaped silicon member 23 and a pair of the semiconductor pillars 28 (SPs) and 28 (SPb) connected to the upper end portions of the two semiconductor pillars 24 constituting the U-shaped silicon member 23.

A method of manufacturing the semiconductor memory device according to the first embodiment will be described.

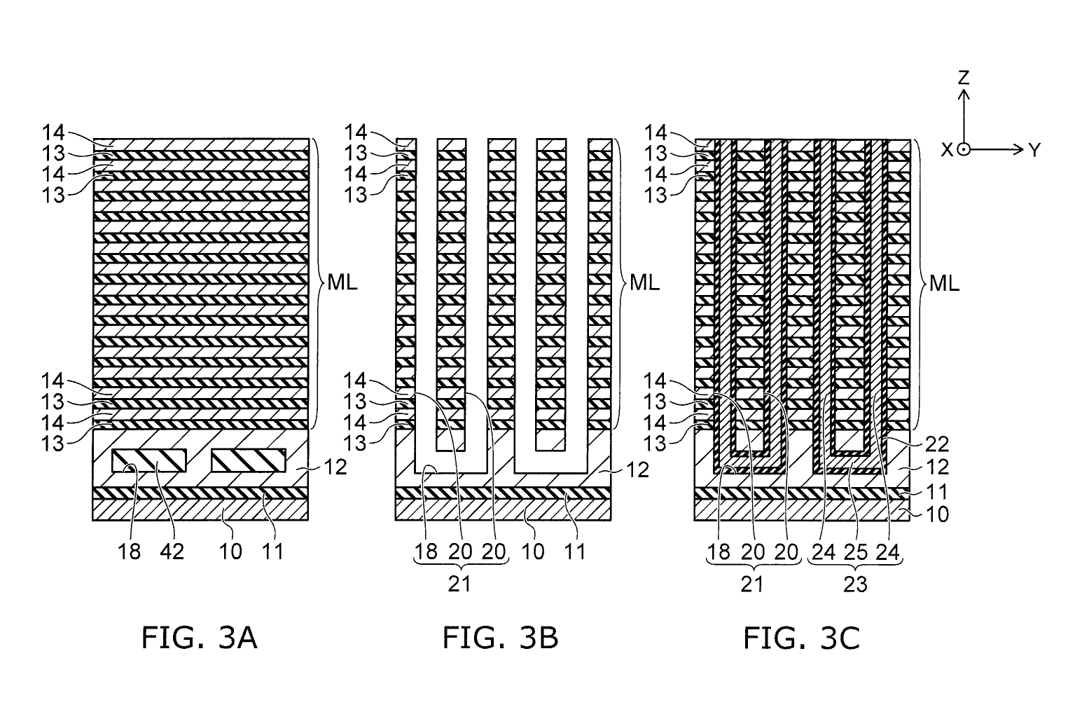

First, FIGS. 3A to 7C are process cross-sectional views illustrating the method of manufacturing the semiconductor memory device according to the first embodiment, and show cross sections corresponding to those taken along line A-A′ of FIG. 1.

Specifically, as shown in FIG. 3A, the insulating film 11 and the back gate conductive film 12 are formed on the silicon substrate 10, and the communication hole 18 is formed within the back gate conductive film 12. A sacrifice member 42 is formed within the communication hole 18. The stacked body ML is formed by alternately stacking the insulating film 13 and the electrode film 14 on the back gate conductive film 12.

Next, as shown in FIG. 3B, the through-hole 20 is formed so as to penetrate the stacked body ML and reach the communication hole 18, and thus the U-shaped hole 21 is formed. Then, the sacrifice member 42 within the communication hole 18 is removed.

Subsequently, as shown in FIG. 3C, the memory film 22 is formed on the inner face of the U-shaped hole 21, and an impurity-doped semiconductor material is embedded within the U-shaped hole 21, with the result that the semiconductor pillar 24 and the connection member 25 constituting the U-shaped silicon member 23 are formed.

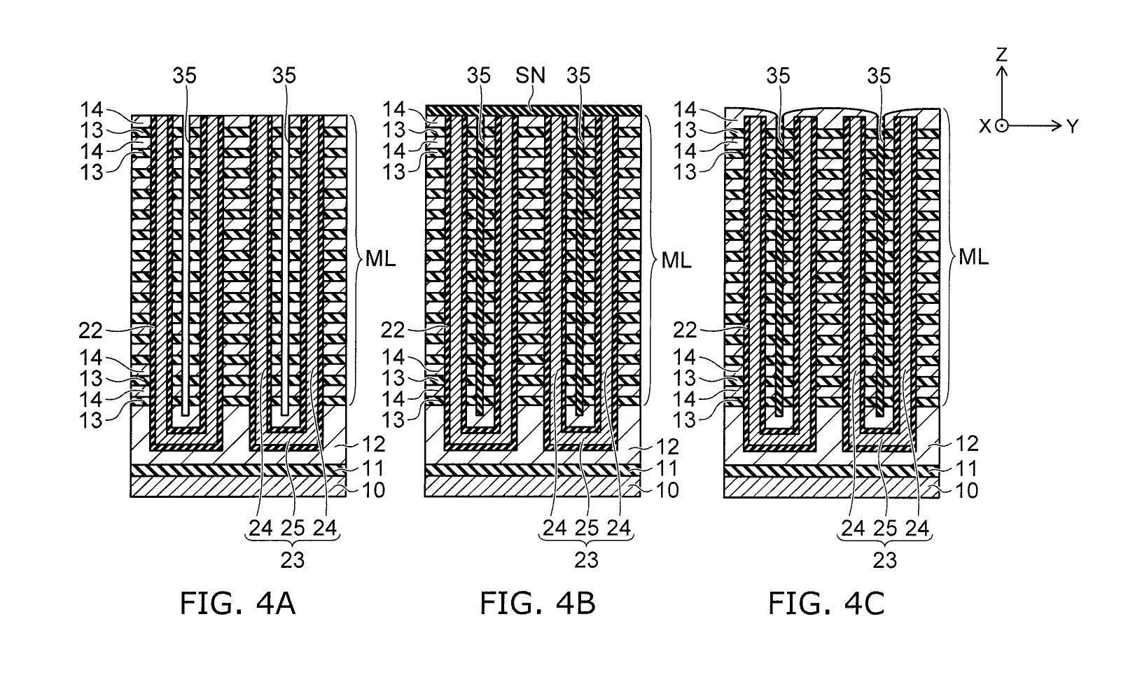

After that, as shown in FIG. 4A, a slit 35 that is a first slit is formed along the X-direction so as to divide the stacked body ML. The slit 35 is formed so as to pass through an area directly above the center portion of the connection member 25 in the Y-direction.

Then, as shown in FIG. 4B, on the upper face of the stacked body ML, an insulating film SN that is a second member is formed through the use of, for example, a silicon nitride film or the like. At this time, the slit 35 is embedded with the insulating film that is made of a silicon nitride film or the like and that is a first member.

Subsequently, as shown in FIG. 4C, the insulating film SN is moved backward, for example, by overall etching. In this way, a recess is generated in an area directly above the slit 35 on the upper face of the insulating film SN. On the other hand, no recess is generated in the region other than the area directly above the slit 35 on the upper face of the insulating film SN.

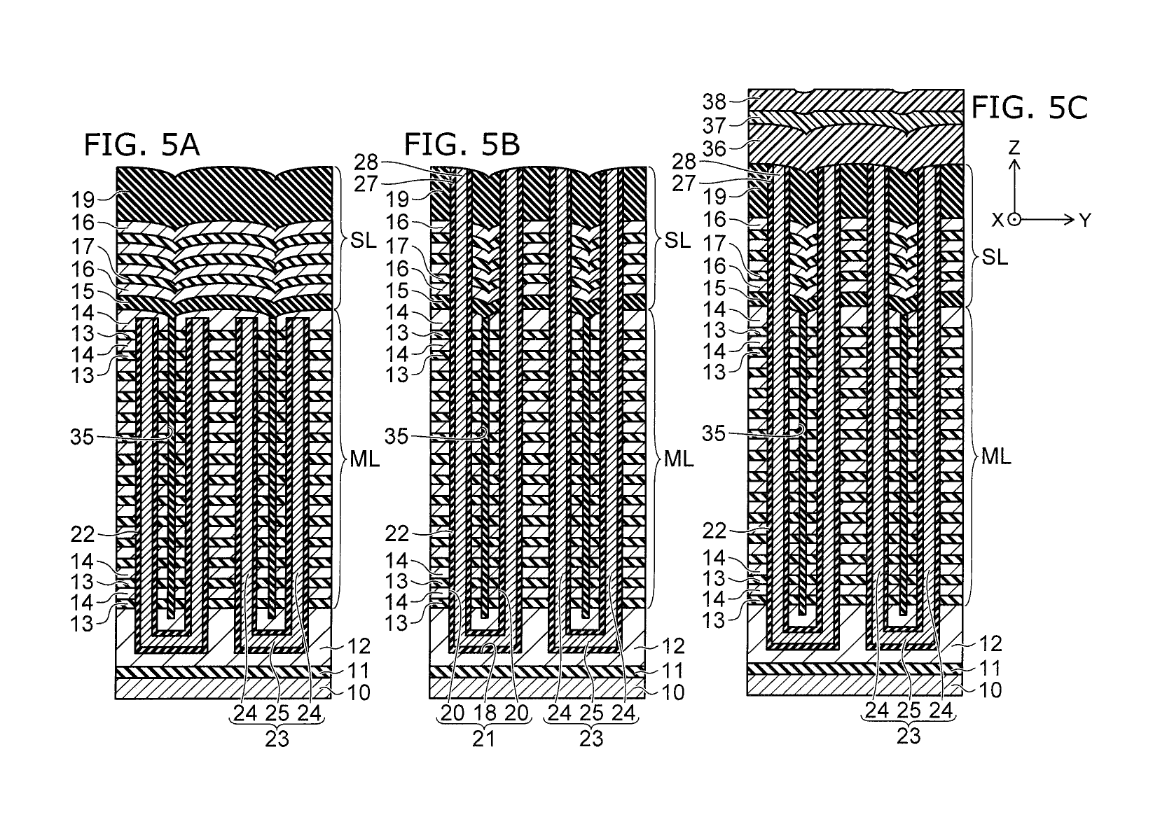

Then, as shown in FIG. 5A, the insulating film 15 is formed on the stacked body ML, a plurality of electrode films 16 and insulating films 17, for example, 7 layers are alternately formed on the insulating film 15, and the insulating film 19 is formed on the uppermost face of the electrode film 16. Thereby, the stacked body SL made of the insulating films 15, 17 and 19 and the electrode film 16 is formed on the stacked body ML. The upper face of the stacked body SL is formed in a shape reflecting the shape of the upper face of the stacked body ML, and a recess is formed in the area directly above the slit 35.

After that, as shown in FIG. 5B, the through-hole 26 is formed in the area directly above the through-hole 20 forming the U-shaped hole 21. The through-hole 26 penetrates the stacked body SL. The gate insulating film 27 is formed on the inner face of the through-hole 26, and the semiconductor pillar 28 is formed by embedding an impurity-doped semiconductor material within the through-hole 26.

Next, as shown in FIG. 5C, on the insulating film 19, for example, an APF (Advanced Patterning Film) is formed as a mask member 36. A recess is also formed in the area directly above the slit 35, also on the upper face of the mask member 36. Furthermore, in addition to a carbon-containing film such as the APF, for example, an oxide film and a nitride film can also be used as the mask member 36.

On the APF, for example, DARC (registered trademark) [dielectric anti-reflective coating] is formed as an anti-reflective film 37, and on the DARC, for example, BARC (registered trademark) [bottom anti-reflective coating] is formed as an anti-reflective film 38. A recess is formed in the area directly above the slit 35 on the upper face of the anti-reflective film 38.

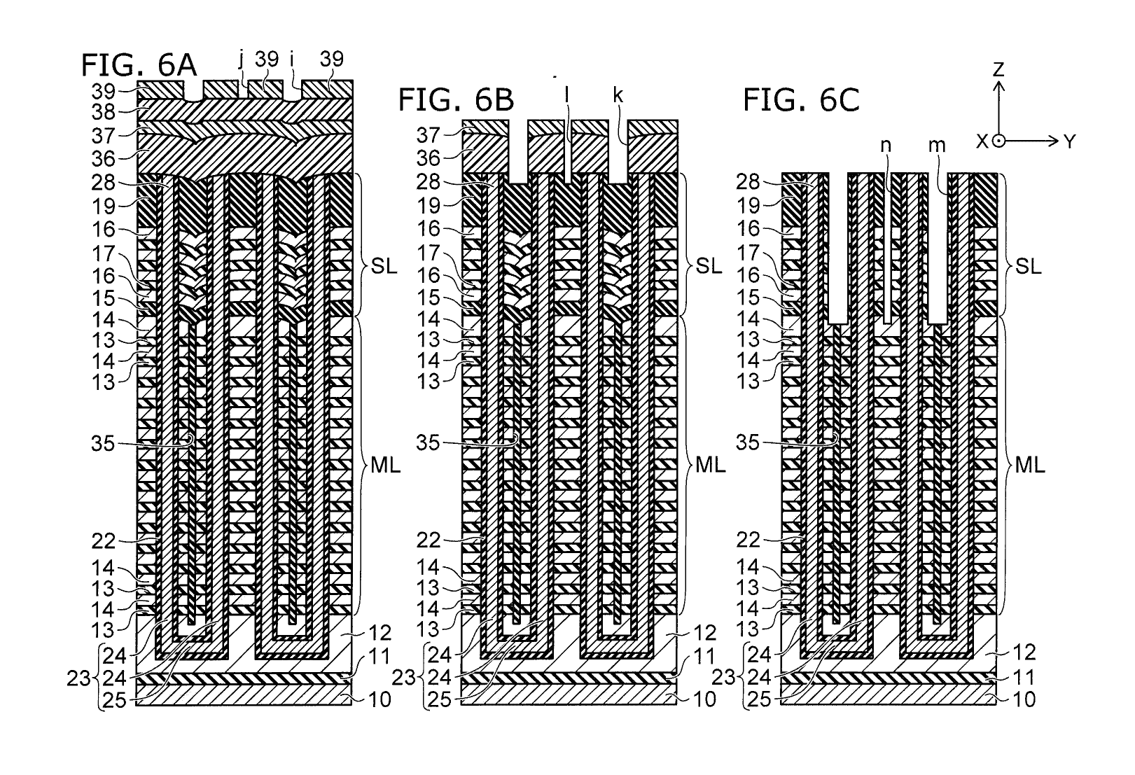

Then, as shown in FIG. 6A, a resist pattern 39 is formed on the anti-reflective film 38. The resist pattern 39 is formed by processing a resist film through the use of, for example, a photolithography method. In the resist film, the area directly above the slit 35 and an area directly above a region equidistant from the two slits 35 adjacent to each other in the Y-direction are opened. Thereby, a groove portion i that is a first opening portion is formed in the area directly above the slit 35 in the resist film, and a groove portion j that is a second opening portion is formed in the area directly above the region equidistant from the two slits 35 adjacent to each other in the Y-direction, with the result that the resist pattern 39 is formed.

The recess formed in the anti-reflective film 38 exists in the bottom face of the groove portion i, and thus there are slight differences in the width, the depth and the like between the groove portion i and the groove portion j in the resist pattern 39.

Next, as shown in FIG. 6B, anisotropic etching is performed on the anti-reflective film 37 and the mask member 36 by subjecting the resist pattern 39 as a mask to a reactive ion etching (RIE), with the result that a groove portion k is formed under the groove portion i and a groove portion l is formed under the groove portion j. At this time, the width of the groove portion k in the Y-direction is formed to be larger than that of the groove portion l in the Y-direction.

Subsequently, as shown in FIG. 6C, anisotropic etching is performed on the stacked body SL by subjecting the anti-reflective film 37 and the mask member 36 as a mask to a reactive ion etching (RIE), with the result that a groove portion m that is a second slit is formed under the groove portion k and a groove portion n that is a third slit is formed under the groove portion l. The anti-reflective film 37 is also removed by this etching. At this time, the width of the groove portion m in the Y-direction is formed to be larger than that of the groove portion n in the Y-direction. The mask member 36 remaining is peeled off by Asher processing or the like using, for example, oxygen gas. At this time, when a film other than a carbon-containing film like the APF, for example, an oxide film or a nitride film is used as the mask member 36, the peeling-off is carried out by etching such as a reactive ion etching (RIE).

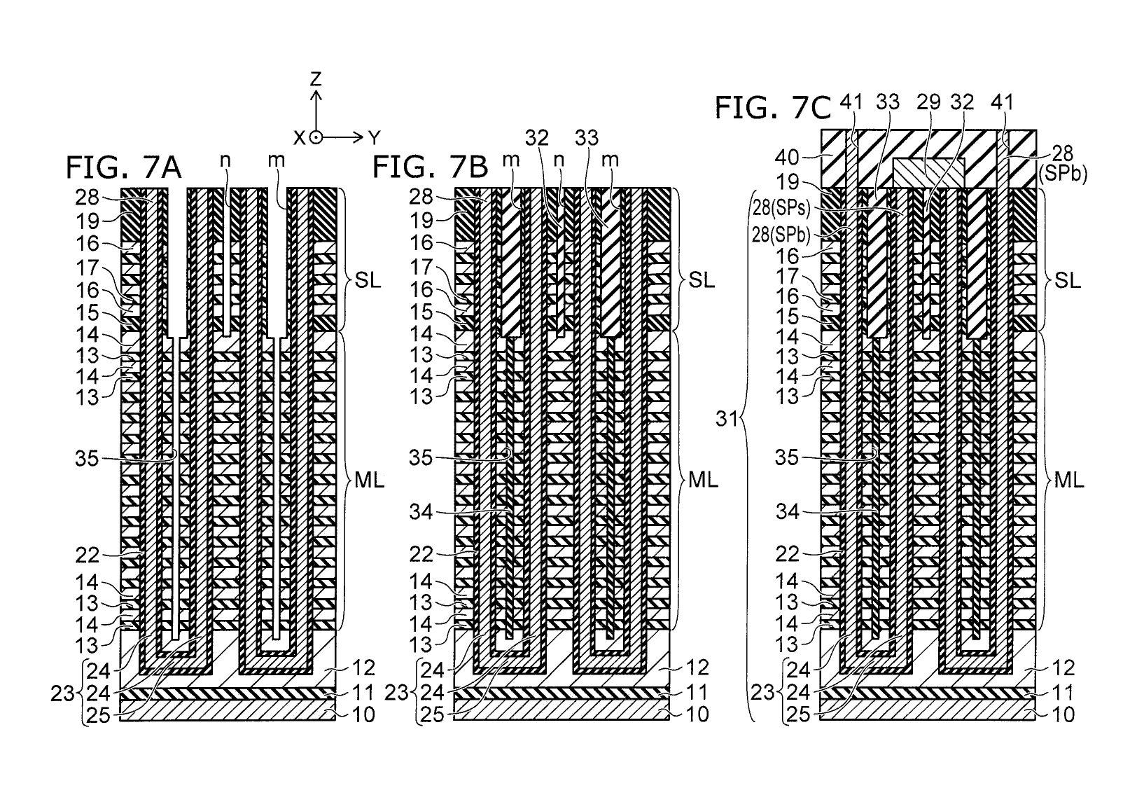

Then, as shown in FIG. 7A, the insulating film made of a silicon nitride film and the like within the slit 35 is removed by isotropic etching, for example, a wet etching method using a hot phosphoric acid solution.

After that, a nickel (Ni) film is formed on the surface of the slit 35 and the surface of the groove portions m and n, and is made to react with the electrode films 14 and 17, and thus the electrode films 14 and 17 are subjected to silicidation. The unreacted nickel (Ni) film after the silicidation reaction is removed.

Next, as shown in FIG. 7B, the insulating members 32, 33 and 34 are formed within the groove portions m and n and the slit 35. The insulating member 32 is formed within the groove portion n, and the insulating member 33 is formed within the groove portion m. In addition, the insulating member 34 is formed within the slit 35.

Then, as shown in FIG. 7C, the source line electrode 29 is formed on the insulating film 19. The source line electrode 29 is formed in an area directly above a region equidistant from the two insulating members 34 adjacent to each other in Y-direction. At this time, the two semiconductor pillars 28 (SPs) adjacent to each other in the Y-direction are connected to the lower face of both end portions of the source line electrode 29.

Subsequently, the insulating film 40 is formed on the insulating film 19 so as to cover the source line electrode 29. A through-hole 41 is formed by lithography and a RIE method, in a part that corresponds to the area directly above the semiconductor pillar 28 (SPb) of the insulating film 19 when seen in the Z-direction. Then, polysilicon is embedded in the through-hole 41, and the semiconductor pillar 28 (SPb) is extended.

After that, as shown in FIG. 2, a plurality of bit lines 30 extending in the Y-direction are formed on the insulating film 19. Thereby, the semiconductor pillars 28 (SPb) aligned in one row in the Y-direction are connected to the same bit line 30.

In this way, the semiconductor memory device according to the embodiment is formed.

Next, the effects of the embodiment will be described with reference to FIGS. 6A and 6C.

As shown in FIG. 6A, in the semiconductor memory device according to the embodiment, a recess is formed in the vicinity of the area directly above the slit 35, in the electrode film 14 on the uppermost face of the stacked body ML. Thereby, in the insulating films 15 and 19, the stacked body SL, the mask member 36 and the anti-reflective film 37, a recess is formed in the area directly above the slit 35 such that the recess formed in the electrode film 14 is taken over. In the subsequent process, the resist pattern 39 is formed by a photolithography method or the like. At this time, the reflectance for exposure is changed by a difference in the film thickness of the anti-reflective film or the like, and thus in the groove portion i and the groove portion j, slight differences in the width and the depth of the groove portions are produced. In this case, as shown in FIG. 6B, when the stacked body SL is etched by a reactive ion etching (RIE) method, the progress in the etching differs between the groove portion i and the groove portion j.

In this case, the progress in the etching of the groove portion i is faster than that in the etching of the groove portion j. Such a difference in the progress of the etching causes a further difference in the progress of the etching of each groove portion in the subsequent process. Thereby, as shown in FIG. 6C, the width of the groove portion m in the Y-direction is formed to be larger than that of the groove portion n in the Y-direction. In addition, in the process preceding the silicidation, when the insulating film made of a silicon nitride film or the like within the slit 35 is removed, a chemical solution is easily put in due to the large width of the groove portion m. Furthermore, when the silicidation reaction is performed on the surface of the groove portion m and the surface of the slit 35, a nickel (Ni) film is easily formed in the groove portion m due to the large width of the groove portion m, and the removal of an unnecessary unreacted substance after the reaction is facilitated, with the result that the efficiency of the silicidation is enhanced. Moreover, the silicidation region of the selection gate electrode is extended, and thus it is possible to realize the reduction in the resistance of the selection gate electrode. Furthermore, the width of the groove portion m in the Y-direction is wide, whereas the width of the groove portion n in the Y-direction is narrow, and thus it becomes possible to reduce the cell size without reducing the efficiency of the silicidation.

### Second Embodiment

Although the configuration of a semiconductor memory device according to a second embodiment is the same as that of the semiconductor memory device according to the first embodiment, a manufacturing method differs partially.

Next, the method of manufacturing the semiconductor memory device according to the embodiment will be described.

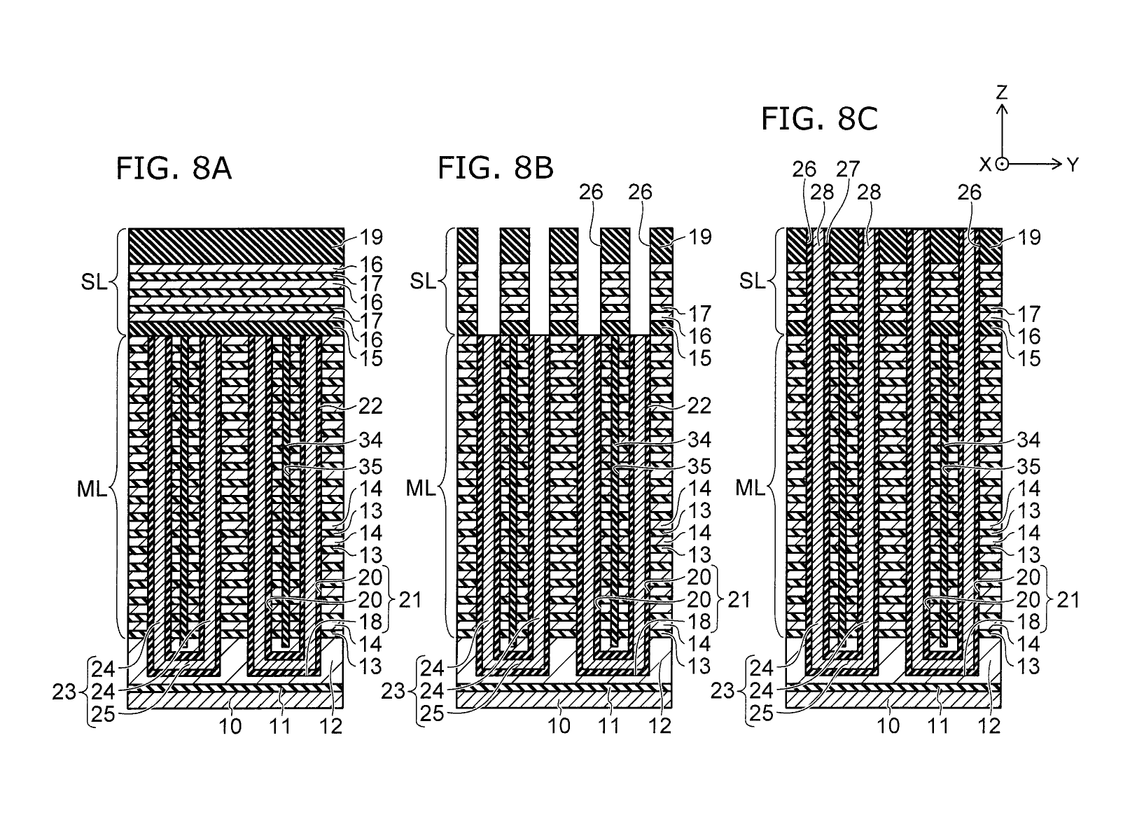

FIGS. 8A to 10 are process cross-sectional views illustrating the method of manufacturing the semiconductor memory device according to the second embodiment, and show cross sections corresponding to those taken along line A-A′ of FIG. 1.

First, the insulating film 11 and the back gate conductive film 12 are formed on the silicon substrate 10, and the communication hole 18 is formed within the back gate conductive film 12. The stacked body ML is formed on the back gate conductive film 12 by alternately stacking the insulating film 13 and the electrode film 14. Then, the through-hole 20 is formed so as to penetrate the stacked body ML to thereby reach the communication hole 18, and thus the U-shaped hole 21 is formed. After that, the slit 35 is formed along the X-direction so as to divide the stacked body ML. Then, the memory 22 is formed on the inner face of the U-shaped hole 21, and an impurity-doped semiconductor material is embedded within the U-shaped hole 21, with the result that the semiconductor pillar 24 and the connection member 25 constituting the U-shaped silicon member 23 are formed.

Subsequently, as shown in FIG. 8A, for example, the insulating film 15 made of a silicon nitride film or the like is formed on the upper face of the stacked body ML. At this time, the slit 35 is embedded with the insulating film that is made of a silicon nitride film or the like and that is the first member. A plurality of electrode films 16 and insulating films 17, for example, a total of 7 layers are alternately formed on the insulating film 15, and the insulating film 19 is formed thereon. The stacked body SL is formed. Thereby, the insulating films 15, 17 and 19 and the electrode film 16 constitute the stacked body SL. The surface of each layer of the stacked body SL is formed so as to be a horizontal face.

Thereafter, as shown in FIG. 8B, the through-hole 26 is formed in the area directly above the through-hole 20 forming the U-shaped hole 21 of the stacked body SL. The through-hole 26 penetrates the stacked body SL.

After that, as shown in FIG. 8C, the gate insulating film 27 is formed on the inner face of the through-hole 26, and an impurity-doped semiconductor material is embedded within the through-hole 26, with the result that the semiconductor pillar 28 is formed.

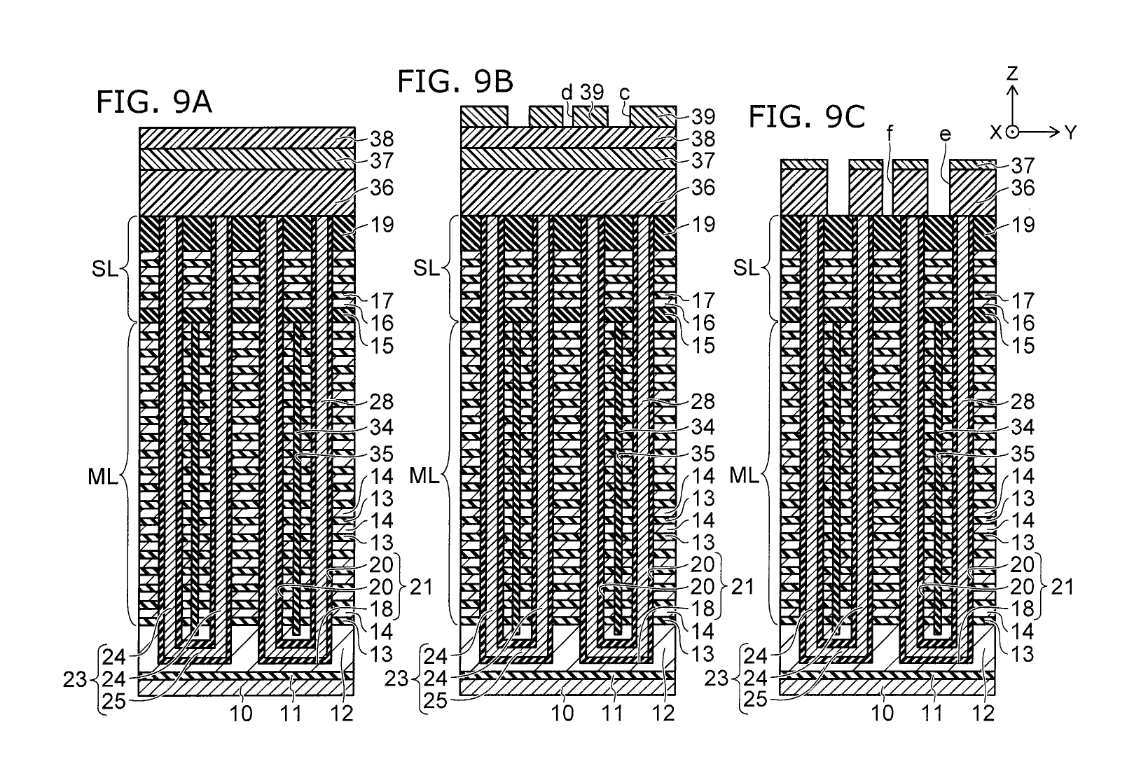

Next, as shown in FIG. 9A, for example, an APF is formed as the mask member 36 on the insulating film 19. Furthermore, also in addition to a carbon-containing film such as the APF, for example, an oxide film and a nitride film can also be used as the mask member 36.

Subsequently, on the APF, for example, the DARC (registered trademark) is formed as the anti-reflective film 37, and on the DARC, for example, the BARC (registered trademark) is formed as the anti-reflective film 38.

Then, as shown in FIG. 9B, the resist pattern 39 is formed on the anti-reflective film 38. The resist pattern 39 opens the upper portion region of the slit 35 and the area directly above a region equidistant from the two slits 35 adjacent to each other in the Y-direction. Thereby, a groove portion c that is a first opening portion is formed in the upper portion region of the slit 35, and in the upper portion region in the region equidistant from the two slits 35 adjacent to each other in the Y-direction, a groove portion d that is a second opening portion is formed. In addition, the width of the groove portion c in the Y-direction is formed to be larger than that of the groove portion d in the Y-direction. Furthermore, the width of the groove portion c in the Y-direction is formed to be smaller than the distance of the two through-holes 20 adjacent to each other by sandwiching the slit 35 in the Y-direction.

After that, as shown in FIG. 9C, anisotropic etching is performed on the anti-reflective film 37 and the mask member 36 by the reactive ion etching (RIE) method, and thus the groove portion e is formed under a groove portion c and a groove portion f is formed under the groove portion d. At this time, the width of the groove portion e to be formed in the Y-direction is approximately the same as that of the groove portion c in the Y-direction, and the width of the groove portion f in the Y-direction is approximately the same as that of the groove portion d in the Y-direction.

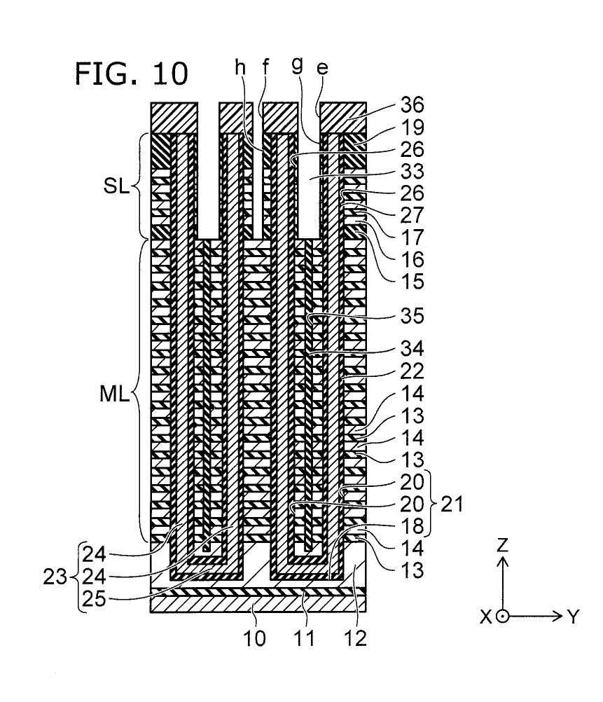

Next, as shown in FIG. 10, anisotropic etching is performed on the insulating films 15 and 19 and the stacked body SL by the reactive ion etching (RIE) method, and thus a groove portion g that is a second slit is formed under the groove portion e and a groove portion h that is a third slit is formed under the groove portion f. At this time, the width of the groove portion g to be formed in the Y-direction is approximately the same as that of the groove portion e in the Y-direction, and the width of the groove portion h in the Y-direction is approximately the same as that of the groove portion f in the Y-direction. Then, the anti-reflective film 37 is removed from the top of the mask member 36.

The subsequent process is the same as in the first embodiment, and the process shown in FIGS. 6C to 7C in the first embodiment is performed.

In this way, the semiconductor memory device according to the embodiment is formed.

The effects of the embodiment will then be described with reference to FIGS. 9B and 10.

As shown in FIG. 9B, in the embodiment, the width of the groove portion c of the resist pattern 39 in the Y-direction is formed to be larger than that of the groove portion d in the Y-direction, and by etching performed in the subsequent process, the lower layers are etched such that the widths of the groove portion c and the groove portion d in the Y-direction are taken over. Consequently, as shown in FIG. 10, the width of the groove portion g in the Y-direction is formed to be larger than that of the groove portion h in the Y-direction. Thereby, in the preceding process where the silicidation is performed, when the insulating film made of a silicon nitride film or the like within the slit 35 is removed, a chemical solution is easily put in. In addition, when the silicidation reaction is performed on the surface of the groove portion g and the surface of the slit 35, it is easy to form a nickel (Ni) film in the groove portion g, and the removal of an unnecessary unreacted substance after the reaction is facilitated, with the result that the efficiency of the silicidation is enhanced. Furthermore, the silicidation region of the selection gate electrode is extended, and thus it is possible to realize the reduction in the resistance of the selection gate electrode. Moreover, it is possible to reduce the cell size without reducing the efficiency of the silicidation, by the increase in the width of the groove portion g in the Y-direction and the decrease in the width of the groove portion h in the Y-direction.

According to the embodiments described above, it is possible to realize the semiconductor memory device in which the resistance of the selection gate electrode is reduced while the increase in the cell size is reduced, and the method of manufacturing it.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Additionally, the embodiments described above can be combined mutually.

What is claimed is:

1. A semiconductor memory device comprising:
a substrate;
a stacked body provided on the substrate, and including a plurality of control gate electrodes and a plurality of insulating films, each of the plurality of control gate electrodes and each of the plurality of insulating films being alternately stacked in a stacking direction;
a selection gate electrode provided on the stacked body;
a first semiconductor pillar extending in the stacking direction and provided in the selection gate electrode and the stacked body;
a first insulating member dividing the stacked body in a first direction;
a second insulating member provided in an area directly above the first insulating member and dividing the selection gate electrode in the first direction; and
a third insulating member provided in a region other than the area directly above the first insulating member and dividing the selection gate electrode in the first direction,
an average width of the second insulating member in the first direction being larger than an average width of the third insulating member in the first direction.

2. The device according to claim 1,
wherein the average width of the second insulating member is larger than an average width of the first insulating member in the first direction.

3. The device according to claim 1,
wherein the second insulating member and the third insulating member are alternately disposed along the first direction.

4. The device according to claim 1,
wherein the selection gate electrode has a silicidation area.

5. The device according to claim 1,
wherein at least a part of a lower face of the selection gate electrode is inclined with respect to an upper face of the substrate.

6. The device according to claim 5,
wherein a distance between an end portion of the selection gate electrode in contact with the second insulating member and the substrate is shorter than a distance between an edge portion facing the first semiconductor pillar of the selection gate electrode and the substrate.

7. The device according to claim 1,
wherein a lower face of the control gate electrode is parallel to an upper face of the substrate, and
at least a part of a lower face of the selection gate electrode is inclined with respect to the upper face of the substrate.

8. The device according to claim 1, further comprising:
an electrode film provided between the substrate and the stacked body;
a second semiconductor pillar extending in the stacking direction and provided in the selection gate electrode and the stacked body;
a connection member provided within the electrode film and connecting the first semiconductor pillar and the second semiconductor pillar;
a bit line connected to an upper end of the first semiconductor pillar; and
a source line connected to an upper end of the second semiconductor pillar.

9. The device according to claim 8,
wherein the first insulating member is disposed between the first semiconductor pillar and the second semiconductor pillar.

10. A semiconductor memory device comprising:
a substrate;
a first stacked body and a second stacked body provided to be adjacent to each other on the substrate, and including a plurality of control gate electrodes and a plurality of insulating films, each of the plurality of control gate electrodes and each of the plurality of insulating films being alternately stacked in a stacking direction;
a first selection gate electrode provided on the first stacked body;
a second selection gate electrode and a third selection gate electrode provided on the second stacked body;
a first semiconductor pillar provided in the first selection gate electrode and the first stacked body, extending in a stacking direction of the first selection gate electrode and the first stacked body;
a second semiconductor pillar provided in the second stacked body and the second selection gate electrode, extending in the stacking direction;
a third semiconductor pillar provided in the second stacked body and the third selection gate electrode, extending in the stacking direction;
memory films provided between the plurality of control gate electrodes and the first semiconductor pillar, between the plurality of control gate electrodes and the second semiconductor pillar, and between the plurality of control gate electrodes and third semiconductor pillar;
an average width of a region between a first selection gate electrode and the second selection gate electrode in a first direction being larger than an average width of a region between the second selection gate electrode and the third selection gate electrode in the first direction.

11. The device according to claim 10, wherein
the average width of the region between the first selection gate electrode and the second selection gate electrode is larger than an average width of a region between the first stacked body and the second stacked body.

12. A method of manufacturing a semiconductor memory device, the method comprising:
forming a stacked body by alternately stacking a control gate electrode and an insulating film alternately on a substrate;
forming a plurality of first semiconductor pillars extending in a stacking direction of the control gate electrode, the insulating film and the stacked body;
forming, in a part between the first semiconductor pillars within the stacked body, a first slit penetrating the stacked body in the stacking direction and extending in a first direction orthogonal to the stacking direction;
forming a first member within the first slit;
forming a selection gate electrode on the stacked body;
forming a second semiconductor pillar extending in the stacking direction, penetrating the selection gate electrode and connected to the first semiconductor pillar;
forming, on the selection gate electrode, a mask member in which a first opening portion extending in the first direction is formed in an area directly above the first slit and in which a second opening portion extending in the first direction is formed in a region other than the area directly above the first slit;
forming, by performing etching by using the mask member as a mask, a second slit penetrating the selection gate electrode in the stacking direction in an area directly above the first opening portion and forming, in an area directly above the second opening portion, a third slit which penetrates the selection gate electrode in the stacking direction and which has an average width smaller than an average width of the second slit;
removing, via the second slit, the first member from an interior of the first slit; and
embedding an insulating material within the first slit, the second slit and the third slit.

13. The method according to claim 12,
wherein an average width of the second slit is formed to be larger than an average width of the first slit.

14. The method according to claim 12,
wherein in the forming the mask member, the first opening portion and the second opening portion are alternately disposed along a second direction orthogonal to both the stacking direction and the first direction.

15. The method according to claim 12,
wherein the forming the first member includes:
embedding the first member within the first slit by depositing the first member; and
locating an upper face of the first member in a position different from an upper face of the stacked body by performing etching under a condition in which an etching rate of the first material is different from an etching rate of the insulating film, and
wherein, in the forming the selection gate electrode, the selection gate electrode is curved by reflecting unevenness of the upper face of the stacked body and the upper face of the first member.

16. The method according to claim 15,
Wherein, in the locating the upper face of the first member in the position different from the upper face of the stacked body, the upper face of the first member is made lower than the upper face of the stacked body by performing etching under a condition in which the etching rate of the first material is higher than the etching rate of the insulating film.

17. The method according to claim 12,
Wherein, in the forming the mask member, an average width of the first opening portion is formed to be larger than an average width of the second opening portion.

18. The method according to claim 12,
wherein the removing the first member is performed by wet etching.

19. The method according to claim 18,
wherein the first member is formed of a silicon nitride film, the control gate electrode is formed of polysilicon and the wet etching is performed using hot phosphoric acid.

20. The method according to claim 12, further comprising:
performing silicidation on a cross section of the selection gate electrode and a cross section of the control gate electrode via the first slit and the second slit.
